(19) United States
(12) Patent Application Publication
(10) Pub. No.: US 2009/0152663 A1
(43) Pub. Date: Jun. 18, 2009

(54) Perforated silicon plate assembly for forming and transferring of silicon thin film solar cells

(76) Inventor: Xiang Zheng Tu, Redwood City, CA (US)

Correspondence Address: Bruce H. Johnsonbaugh;Eckhoff & Hoppe, Suite 2800, 101 Montgomery Street, San Francisco, CA, 94104, US

(21) Appl. No.: 12/002,687

(22) Filed: Dec. 18, 2007

(51) Int. Cl. H01L 31/042

(52) U.S. Cl. 257/439; 438/72; 136/256; 257/E31.11

(57) ABSTRACT

A perforated monocrystalline silicon plate assembly is provided for forming and transferring of monocrystalline silicon thin film solar cells. The assembly comprises a perforated monocrystalline silicon plate with a plurality of through holes and obstructive holes. The assembly is allowed to grow a first p-type epitaxial layer with an inverted pyramid surface on the surface of the silicon plate, which is then selectively converted into a porous silicon layer with an inverted pyramid surface. The assembly is further allowed to grow a second p-type epitaxial layer with an inverted pyramid surface on the surface of the porous silicon layer, which is then used to fabricate a monocrystalline silicon thin film solar cell with an inverted pyramid surface. The assembly further comprises a transferring means for chemically etching of the porous silicon layer so as to transfer the silicon solar cell onto a transparent plate and reuse the assembly for next forming and transferring of a monocrystalline silicon thin film solar cell. The perforated silicon plate assembly can be reused for forming and transferring of a monocrystalline silicon thin film solar cell infinite times. A method for fabricating the assembly mainly comprises steps: performing deep reactive ion etching of a monocrystalline silicon plate to form a plurality of through holes and obstructive holes; growing a first p-type silicon epitaxial layer with an inverted pyramid surface; performing anodization for selectively converting the epitaxial layer into a porous silicon layer with an inverted pyramid surface; growing a second p-type epitaxial layer with an inverted pyramid surface on the surface of the porous silicon layer, fabricating a monocrystalline silicon thin film solar cell with an inverted pyramid surface using the second monocrystalline silicon epitaxial layer; and chemically etching the porous silicon layer for transferring the silicon solar cell onto a transparent plate.

### BACKGROUND OF THE INVENTION

The present invention is related to monocrystalline silicon thin film solar cells and, more particularly, to a perforated monocrystalline silicon plate assembly for forming and transferring of monocrystalline silicon thin film solar cells.

### DESCRIPTION OF RELATED TECHNOLOGY

Many efforts have been made in the enhancement of conversion efficiency and reduction of production costs for production of silicon solar cells. It has been reported that monocrystalline silicon solar cells have high-energy conversion efficiencies up to 24.7% in a laboratory environment. However, these cells have generally been fabricated by very sophisticated processing sequences and require several high-temperature steps at temperatures above 1000° C. as well as numerous photolithography steps. Moreover, the silicon wafer constitutes more than 65% of the total production cost of silicon solar cells or about 50% of the cost of silicon solar cell modules. Due to the complex technology and high cost, it is apparent that an economic mass production of these cells is not possible.

The fabrication of monocrystalline silicon thin film solar cells on foreign substrates is being intensively investigated worldwide in order to produce cheap and efficient solar cells.

A porous silicon layer transfer technique provides an opportunity to get monocrystalline silicon films on low-cost substrates such as glass and plastics. There are many processes developed or being developed which use porous silicon as a sacrificial layer for the monocrystalline silicon solar cell transfer process. Among them are ELTRAN process, SPS process, PSI process, and QMS process.

Each process consists of four common steps: (a) a double porosity structure (high-porosity layer beneath low-porosity layer) formation on starting silicon substrate by anodization. (b) thermal annealing of porous silicon and active layer deposition: annealed low-porosity layer acts as a good seeding layer for epitaxial layer deposition and voids with weak silicon pillars forms in high-porosity layer acts as a separation layer. (c) device fabrication. (d) separation of epitaxial layer from the starting silicon substrate and transfer onto foreign substrate by gluing it with a transparent adhesive layer and applying mechanical force.

Apart from the common steps, each process incorporates several particular fabrication steps.

The ELTRAN process combines a thermal oxidation of porous silicon at 400° C. prior to epitaxial layer deposition in order to stabilize the porous silicon layer against reorganization during sintering and epitaxial growth processes. After the epitaxial layer is transferred onto a foreign substrate, the device fabrication is performed.

In SPS process, most of the device fabrication process is conducted when the epitaxial layer is still attached with the starting silicon substrate.

The PSI process utilizes a textured silicon substrate as the starting substrate unlike polished silicon used in other processes. An epitaxial layer can be grown on the textured surface of the starting substrate that helps in light trapping. After device fabrication a carrier glass substrate is attached to the top layer to separate the device from the starting substrate.

The QMS process means that sintering of porous-silicon at high-temperature results in reorganization of porous silicon. The epitaxial layer is deposited on QMS at 1100° C. by chemical vapor deposition. In order to separate the semi-finished device a glass substrate with transparent resin is attached with it.

In the above-described processes, however, some problems need to be solved.

First, in all these processes the porous silicon layer is formed in the top layer of the silicon substrate so that each solar cell expenses a layer of high-quality silicon material and the silicon substrate is thinned once for each solar cell. The silicon substrate that has been thinned many times may not be reused due to lack of sufficient resistance to the impact of temperature stress, pressure, and mechanical force generated during the fabrication process.

Second, separation of the epitaxial layer from the starting substrate relies on a double porosity structure of the porous layer. In the double porosity structure the high-porosity layer serves as a separation layer. Formation of the separation layer depends on the reorganization of porous silicon during the sintering process that causes the conversion of a high-porosity layer into the silicon pillars. Also the strength of the silicon pillars, which plays a key role in the layer separation step, depends on the porosity of the high-porosity layer. Therefore, the porosity of the high porosity layer needs to be optimized very carefully. If the porosity of the high-porosity layer is high, a premature separation could occur or if the porosity of the high porosity layer is low the required separation of the epitaxial layer from the starting substrate may not occur at all.

Third, separation of the epitaxial layer from the starting substrate using mechanical force such as solid wedge splitting and fluid wedge splitting. With solid wedge splitting the force is applied to the wafer edge so that the wafer is forced to change shape excessively. This entails a risk of damage. In fluid wedge splitting the wedge is required to be constantly change shape so that the pressure is exerted across the entirely region where the splitting is proceeding. To meet these requirements sophisticated equipment is required

Fourth, in the PSI process the surface of a silicon substrate is randomly textured with upright pyramids by etching (100)-oriented, p-type, boron doped silicon wafers in KOH solution, which results not only increasing process complexity but also limiting the use of available processing equipment due to KOH contamination.

Finally, after separation by mechanical force, the residue porous silicon still attached to the separated layers including the epitaxial layer and the starting silicon substrate. To reuse the silicon substrate and finish the device fabrication some sequential etching processes are needed to perform.

### SUMMARY OF CERTAIN INVENTIVE ASPECTS

In order to solve the above-mentioned problems, the present invention provides a perforated monocrystalline silicon plate assembly for forming and transferring of monocrystalline silicon thin film solar cells.

In one aspect of the invention, a perforated monocrystalline silicon plate assembly is provided, whose silicon plate is used to inherently grow a monocrystalline silicon epitaxial layer with an inverted pyramid surface on the surface, which is then selectively converted into a porous silicon layer with an inverted pyramid surface.

In another aspect of the invention, a perforated monocrystalline silicon plate assembly is provided, whose porous silicon layer grown on the surface of the silicon plate is not a double porosity layer, but a single low porosity layer.

In yet another aspect of the invention, a perforated monocrystalline silicon plate assembly is provided, whose porous silicon layer with an inverted pyramid surface gown on the surface of the silicon plate is used to inherently grow another monocrystalline silicon layer with an inverted pyramid surface, which is then processed to form a monocrystalline silicon thin film solar cell with an inverted pyramid surface.

In yet another aspect of the invention, a perforated monocrystalline silicon plate assembly is provided, whose monocrystalline silicon solar cell is transferred onto a foreign substrate without expensing the starting silicon plate at all.

In yet another aspect of the invention, a perforated monocrystalline silicon plate assembly is provided, whose monocrystalline silicon solar cell is transferred onto a foreign substrate by chemical etching instead of mechanical force.

In yet another aspect of the invention, a perforated monocrystalline silicon plate assembly is provided, in which after transferring the surface of the silicon plate is still shiny and can be reused for epitaxy directly.

In a general aspect of the invention, a perforated monocrystalline silicon plate assembly is provided, in which the monocrystalline silicon thin film solar cell can be manufactured by directly expensing tricholosilane instead of the silicon plate, which is produced through a completely process including: silicon powder→tricholosilane→polysilicon ingot→monocrystalline ingot→silicon wafer, so as to manufacture high efficient silicon solar cells at very low cost.

For the purpose of realizing the above-mentioned aspects the present invention provides a perforated monocrystalline silicon plate assembly for forming and transferring of monocrystalline silicon thin film solar cells. The assembly comprises a perforated monocrystalline silicon plate with a plurality of through holes and obstructive holes. The assembly is allowed to inherently grow a first epitaxial layer with an inverted pyramid surface on the surface, which is then selectively converted into a porous silicon layer with an inverted pyramid surface. The assembly is further allowed to inherently grow a second epitaxial layer with an inverted pyramid surface on the surface of the porous silicon layer, which is then used to fabricate a monocrystalline silicon thin film solar cell with an inverted pyramid surface. The assembly is further comprises a transferring means for chemically etching of the porous silicon layer so as to transfer the silicon solar cell onto a transparent plate. The perforated silicon plate assembly can be reused for forming and transferring of monocrystalline silicon thin film solar cells directly and infinite times because it is not allowed for etching, thinning and lift-off during the solar cell fabrication process.

A method for fabricating the assembly comprises main steps: performing deep reactive-ion etching (DRIE) to form a perforated monocrystalline silicon plate having a plurality of through holes and obstructive holes; inherently growing a first silicon epitaxial layer with an inverted pyramid surface on the surface of the silicon plate; performing anodization for selectively converting the epitaxial layer into a porous silicon layer with an inverted pyramid surface; inherently growing a second epitaxial layer with an inverted pyramid surface on the surface of the porous silicon layer, fabricating a monocrystalline silicon thin film solar cell with an inverted pyramid surface using the second monocrystalline silicon epitaxial layer; and chemically etching of the porous silicon layer for transferring the solar cell onto a transparent plate.

A more complete understanding of the present invention, as well as further features and advantages of the present invention, will be obtained by reference to the following detailed description and drawings.

### BRIEF DESCRIPTION OF THE DRAWINGS

FIG. 1A a is cross-sectional view of a perforated monocrystalline silicon plate with a plurality of through holes and obstructive holes, which is used for forming and transferring of monocrystalline silicon thin film solar cells according to the first embodiment of the present invention.

FIG. 1B is a cross-sectional view of the perforated silicon plate having a monocrystalline silicon thin film solar cell with an inverted pyramid surface, which is mounted on the surface of a porous silicon layer according to the first embodiment of the present invention.

FIG. 2A a is cross-sectional view of a perforated monocrystalline silicon plate assembly with a hole matrix including a plurality of through holes and obstructive holes, which is used for forming and transferring of silicon thin film solar cells according to the second embodiment of the present invention.

FIG. 2B is a cross-sectional view of the perforated monocrystalline silicon plate assembly having a silicon thin film solar cell with an inverted pyramid surface, which is mounted on the surface of a porous silicon layer with according to the second embodiment of the present invention.

FIG. 2C is a cross-sectional view of the silicon thin film solar cell with an inverted pyramid surface, which is separated from the perforated silicon plate assembly, which is done in a transferring system filled with a diluted alkaline solution according to the second embodiment of the present invention.

FIG. 3A shows a method for fabricating a perforated monocrystalline silicon plate assembly for forming and transferring of monocrystalline silicon thin film solar cells at fabrication step 1, in which a monocrystalline silicon plate is processed to form a plurality of through holes and obstructive holes and a low resistance layer disposed on the backside according to the first embodiment of the present invention.

FIG. 3B shows a method for fabricating a perforated monocrystalline silicon plate at fabrication step 2, in which a first p-type silicon epitaxial layer with an inverted pyramid surface is anodized to form a porous silicon layer with an inverted pyramid surface, which is done in an single chamber porous silicon formation system according to the first embodiment of the present invention.

FIG. 3C shows a method for fabricating a perforated monocrystalline silicon plate at fabrication step 3, in which a second p-type silicon epitaxial layer with an inverted pyramid surface is processed to form a silicon thin film solar cell with an inverted pyramid surface, which has a bonded transparent plate on the back surface according to the first embodiment of the present invention.

FIG. 4A is a cross-sectional view of a perforated monocrystalline silicon plate assembly for forming and transferring of monocrystalline silicon thin film solar cells at fabrication step 1, in which a monocrystalline silicon plate is processed to form a holes matrix with a plurality of through holes and obstructive holes, a buffer trench, a principle supporting frame, a protection film; and an ion conductive according to the second embodiment of the present invention.

FIG. 4B a cross-sectional view of a perforated monocrystalline silicon plate assembly at fabrication step 2, in which the silicon plate is further processed to form an additional supporting frame bonded onto the back surface according to the second embodiment of the present invention.

FIG. 4C cross-sectional view of a perforated monocrystalline silicon plate assembly at fabrication step 3, in which a first p-type silicon epitaxial layer with an inverted pyramid surface is grown on the surface of the hole matrix by confined epitaxial growth according to the second embodiment of the present invention.

FIG. 4D a cross-sectional view of a perforated monocrystalline silicon plate assembly at fabrication step 4, in which the first p-type silicon epitaxial layer with an inverted pyramid surface is selectively converted into a porous silicon layer with an inverted pyramid surface, which is done in a double chamber porous silicon formation system according to the second embodiment of the present invention

FIG. 4E cross-sectional view of a perforated monocrystalline silicon plate assembly at fabrication step 5, in which a second p-type silicon epitaxial layer with an inverted pyramid surface is grown on the porous silicon layer by confined epitaxial growth according to the second embodiment of the present invention.

FIG. 4F a cross-sectional view of a perforated monocrystalline silicon plate assembly at fabrication step 6, in which the second silicon epitaxial layer with an inverted pyramid surface is processed to form a silicon thin film solar cell with an inverted pyramid surface and a transparent plate is bonded thereon according to the second embodiment of the present invention.

FIG. 4G a cross-sectional view of a perforated monocrystalline silicon plate assembly at fabrication step 7, in which the silicon thin film solar cell with an inverted pyramid surface is separated from the perforated silicon plate assembly, which is done in a transferring system filled with a diluted alkaline solution according to the second embodiment of the present invention.

### DETAILED DESCRIPTION OF CERTAIN INVENTIVE EMBODIMENTS

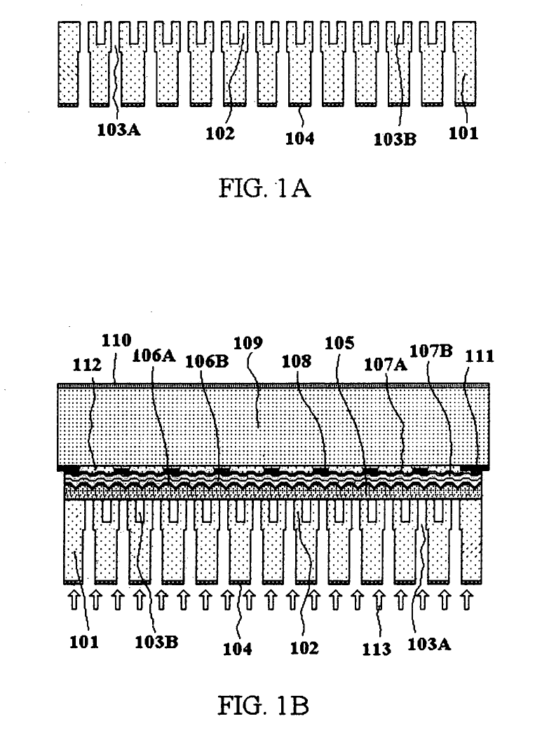

FIG. 1A and FIG. 1B show a perforated monocrystalline silicon plate assembly for forming and transferring of monocrystalline silicon thin film solar cells provided by a first embodiment of the present invention.

Reference to FIG. 1A, a perforated monocrystalline silicon plate assembly for forming and transferring of silicon thin film solar cells comprises a monocrystalline silicon plate 101, a plurality of hole inter-spacers 102, a plurality of through holes 103A, a plurality of obstructive holes 103B, and a low resistance layer 104.

The through holes 103A and obstructive holes 103B are disposed over the entire silicon substrate 101 and distributed along two perpendicular directions (X-Y directions) so that between each two adjacent through holes there are N obstructive holes and the number N ranges from 1 to 100. The size of the silicon plate 101 ranges from 3 to 12 inches in length and the thickness ranges from 100 to 1000 microns. The shape of the silicon plate 101 is preferred to be square. As an alternative, the shape of the silicon plate 101 is circular. The silicon plate 101 is p-type doped and has a carrier concentration ranging from 1×10¹⁴ to 8×10¹⁵ cm³. As an alternative, the silicon plate 101 is n-type doped and has a carrier concentration ranging from 1×10¹⁴ to 1×10¹⁶ cm³. The hole size of the through holes 103A and obstructive holes 103B ranges from 2 to 20 microns in length and the hole pitch ranges from 4 to 40 microns. The depth of the obstructive holes 103B ranges from 10 to 50 microns. The shape of the holes is preferred to be square. As an alternative, the shape of the holes is circular. The through holes 103A comprises a narrow upper portion with a depth ranging from 30 to 100 microns and a wider lower portion with a hole size ranging from 5 to 100 microns. The low resistance layer 104 is disposed on the backside of the silicon plate 101 and comprises of a diffusion layer, which is doped with a similar conduction type impurity to the silicon plate 101 and has a sheet resistance ranging from 1 to 20 ohm/square.

Reference to FIG. 1B, the perforated silicon plate assembly further comprises a monocrystalline silicon thin film solar cell with an inverted pyramid surface and a transparent plate 109. The silicon solar cell consists of a porous silicon layer 105 with an inverted pyramid surface, which is disposed on the surface of the silicon plate 101, a P-N junction including a p⁺-layer 106A, a p-layer 106B, an n⁺-layer 107A, and an n-payer 107B, and a metal contact pattern 108. The transparent plate 109 comprises of glass, plastics or the like, and has an antireflective film 110 on the front surface, a metal contact pattern 111 on the back surface. The transparent plate 109 is bonded onto the top surface of the P-N junction by applying a transparent adhesive layer 112.

As shown in FIG. 1C, a diluted alkaline solution can reach the porous silicon layer 105 via through holes 103A. The diluted alkaline solution comprises of KOH, NaOH or the like and is used to etch the porous silicon 105, but not the silicon plate 101. After etching the porous silicon layer 105 the silicon solar cell is separated from the silicon plate 101 and transferred onto the transparent plate 109.

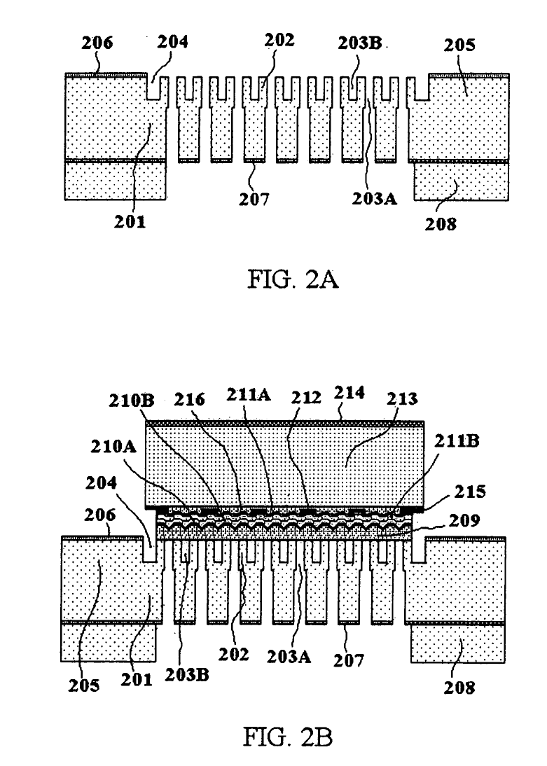

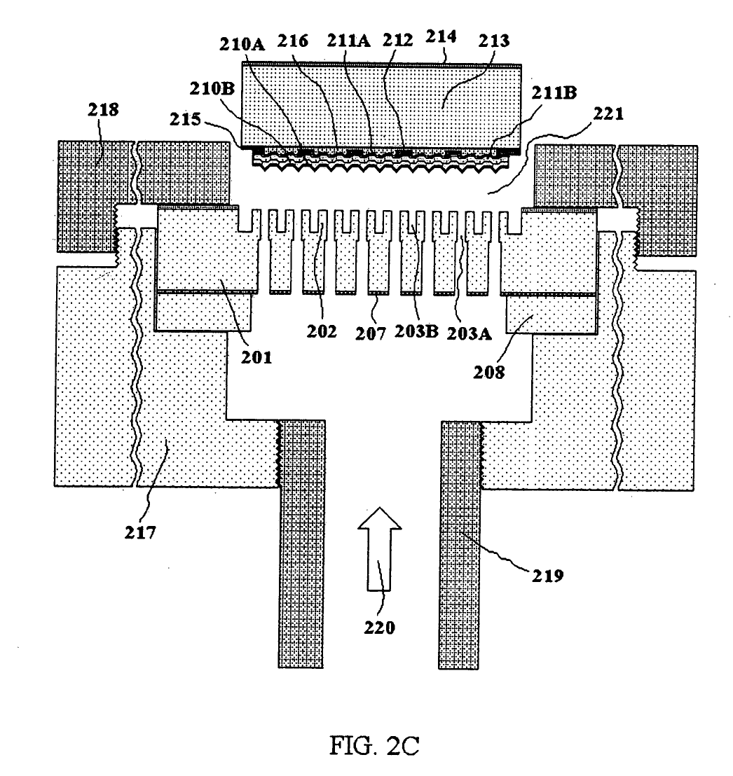

FIG. 2A, FIG. 2B, and FIG. 2C. show a perforated monocrystalline silicon plate assembly for forming and transferring of monocrystalline silicon thin film solar cells provided by a second embodiment of the present invention.

Reference to FIG. 2A, a perforated monocrystalline silicon plate assembly for forming and transferring of silicon thin film solar cells comprises a monocrystalline silicon plate 201, a holes matrix including a plurality of hole inter-spacers 202, a plurality of through holes 203A, a plurality of obstructive holes 203B, which is disposed in the central region of the silicon plate 201, a buffer trench 204 recessed into the silicon plate 201 and surrounding the holes matrix, a principle supporting frame 205 extending from the outer side of the buffer trench 204 to the edge of the silicon plate 201, a protection film 206 disposed on the surface of the principle supporting frame 205 and the internal surface of the buffer trench 204, and an ion conductive electrode 207 disposed on the backside of the silicon plate 201.

The silicon plate 201 is p-type doped and has a carrier concentration ranging from 1×10¹⁴ to 8×10¹⁵ cm³. As an alternative, the silicon plate 201 is n-type doped and has a carrier concentration ranging from 1×10¹⁴ to 1×/10¹⁶ cm³. The size of the silicon plate 201 ranges from 3 to 12 inches in length and its thickness ranges from 100 to 1000 microns. The area occupied by the holes matrix from ⅔ to ⅚ of the area of the silicon plate 201. The shape of the holes matrix is preferred to be square. The through holes 203A and obstructive holes 203B are distributed in two perpendicular directions (X-Y directions) so that between each two adjacent through holes there are N obstructive holes and the number N ranges from 1 to 100. The hole size of the through holes 203A and obstructive hole 203B ranges from 2 to 20 microns and the hole pitch ranges from 4 to 40 microns. The depth of the obstructive holes 203B ranges from 10 to 50 microns. The shape of the holes is preferred to be square. As an alternative, the shape of the holes is circular. The through holes 203A comprises a narrow upper portion with a depth ranging from 30 to 100 microns and a wider lower portion with a hole size ranging from 5 to 100 microns. The width and depth of the buffer trench 204 ranges from 10 to 50 microns and from 10 to 50 microns, respectively. The protection film 206 comprises of amorphous silicon carbide with a thickness ranging from 1000 angstroms to 2 microns. As an alternative, the protection film 205 comprises of low stress silicon nitride with a thickness ranging from 1000 angstroms to 2 microns. The ion conductive electrode 207 comprises of a diffusion layer, which is doped with a similar conduction type impurity to the silicon plate 201 and has a sheet resistance ranging from 1 to 20 ohm/square.

The perforated silicon plate assembly further comprises an additional silicon frame 208 with a thickness ranging from 100 to 2000 microns for enhancing the mechanical strength of the principle plate 205. The silicon frame 208 is managed to match the holes matrix so that the backside of holes matrix can communicate with the outside of the silicon plate 201.

Reference to FIG. 2B, the perforated silicon plate assembly further comprises a ingle crystal silicon thin film solar cell having an inverted pyramid surface and consisting of a P-N junction including a p⁺-layer 210A, a p-layer 210B, an n⁺-layer 211A, an n-layer 211B, which is disposed on the surface of the porous silicon layer 209, a metal contact pattern 212 disposed on the surface of the P-N junction, and a transparent plate 213 with an antireflective film 214 on the front surface and a metal connection 215 on the back surface, which is bonded onto the top surface of the P-N junction by applying a transparent adhesive 216.

Reference to FIG. 2C, the perforated silicon plate assembly further comprises a transferring system consisting of a housing 217 for holding the silicon plate 201, a cover 218 with an outer ring for pressing the silicon plate 201 in place and a central window for revealing the silicon solar cell, a tube 219 exposing the backside of the hole matrix to a diluted alkaline solution 220 for etching porous silicon layer 209 comprising of KOH, NaOH or the like.

As shown in FIG. 2C, the porous silicon layer 209 is etched away to form a gap 221 by the diluted alkaline solution 220 and the silicon solar cell is transferred onto the transparent plate 213 entirely.

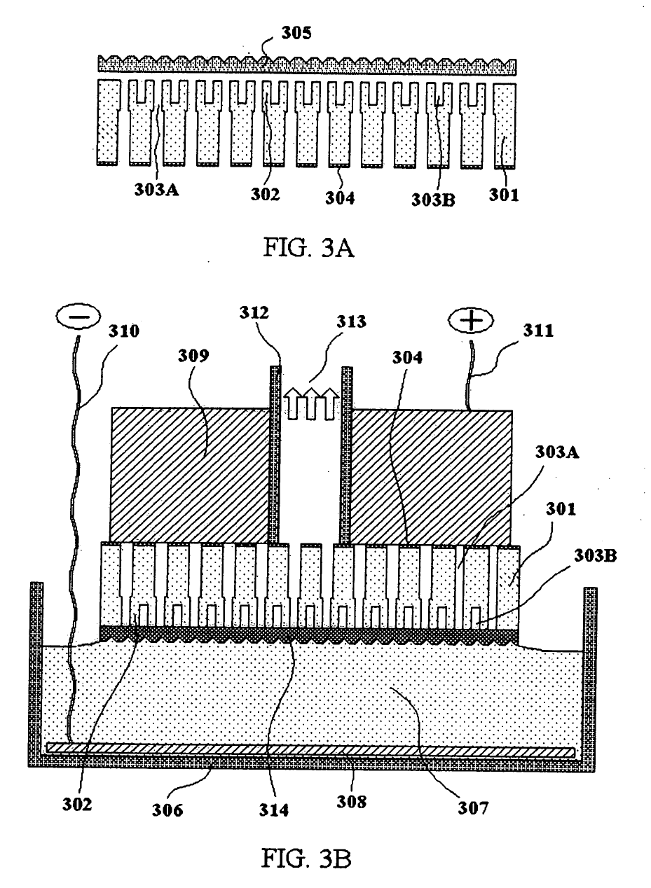

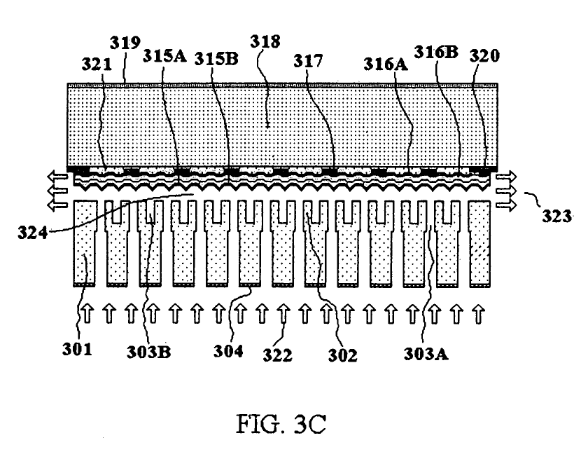

According to the first embodiment of the present invention a method for fabricating a perforated monocrystalline silicon plate assembly for forming and transferring of monocrystalline silicon thin film solar cells is shown as FIG. 3A to FIG. 3C.

FIG. 3A shows a cross-sectional view of a perforated monocrystalline silicon plate assembly for forming and transferring of monocrystalline silicon thin film solar cells at fabrication step 1. At this step, a monocrystalline silicon plate 301 is processed by deep reactive ion etching (DRIE) to form a plurality of holes inter-spacers 302, a plurality of through holes 303A, a plurality of obstructive holes 303B. It is also formed a low resistance layer 304 by thermal diffusion.

The silicon plate 301 is preferred to be a (100) crystalline direction silicon wafer with two opposite surface polished. As an alternative, the silicon plate 301 is a (111) crystalline direction silicon wafer with two opposite surface polished. The shape of the silicon plate 301 is preferred to be square. As an alternative, the shape of the silicon plate 301 is circular. The size of the silicon plate 301 ranges from 3 to 12 inches in length and its thickness ranges from 100 to 1000 microns. It is preferred that the silicon plate 301 is p-type doped and has a carrier concentration ranging from 1×10¹⁴ to 8×10¹⁵ cm³. As an alternative, the silicon plate 301 is n-type doped and has a carrier concentration ranging from 1×10¹⁴ to 1×10¹⁶ cm³. The silicon plate 301 is perforated by deep reactive ion etching so as to form a plurality of hole inter-spacers 302, a plurality of through holes 303A, and a plurality of obstructive holes 303B. The through holes 303A and obstructive holes 303B are distributed in two perpendicular directions (X-Y directions) so that between each two adjacent through holes there are N obstructive holes and the number N ranges from 1 to 100. The hole size ranges from 2 to 20 microns. The hole pitch ranges from 4 to 40 microns and the depth of the obstructive holes ranges from 10 to 50 microns. The shape of the holes is preferred to be square. As an alternative, the shape of the holes is circular. The through holes 303A comprises a narrow upper portion with a depth ranging from 30 to 100 microns and a wider lower portion with a hole size ranging from 5 to 100 microns. The low resistance layer 304 is disposed on the backside of the silicon plate 301 and comprises of a diffusion layer, which is doped with a similar conduction type impurity to the silicon plate 301 and has a sheet resistance ranging from 1 to 20 ohm/square.

As shown in FIG. 3A, a first silicon epitaxial layer 308 with an inverted pyramid surface is grown on the surface of the silicon plate 301. The epitaxy utilizes high-temperature chemical vapor deposition, which is well established in industry. SiHCl₃ (trichlorosilane) is used as silicon source gas for film growth at 1100° C. at a rate of 1 microns/min. BH₂ is added for p-type doping. As an alternative, SiH₂Cl₂(dichlorosilane) is used as silicon source gas and diluted from 0.5 to 3% in H₂ as carrier gas. Growth temperature varies between 1050 and 1100° C. Diluted diborane BH is used for in situ p-type doping. According to the dilution rate, silicon growth rate varies from 0.5 to 2 microns/min. Prior to epitaxy wafer clean is in-situ by hydrogen prebake. The epitaxy starts from the surface of the holes inter-spacers 302. Due to lateral overgrowth, the epitaxial layer grows out of the surface of the hole inter-spacers 302, spreading laterally over the through holes 303A and obstructive holes 303B. In a result, the through holes 303A and obstructive holes 303B are finally seated by he lateral grown epitaxial layer and the surface of the epitaxial layer becomes inverted pyramid surface inherently. The first epitaxial layer 308 with an inverted pyramid surface has a resistivity ranging from 0.1 to 0.001 ohm-cm and a thickness ranging from 2 to 20 microns.

FIG. 3B shows a cross-sectional view of a perforated silicon plate assembly at fabrication step 2. At this step, the first silicon epitaxial layer 305 with an inverted pyramid surface is selectively converted into a porous silicon layer 314 with an inverted pyramid surface by anodization in a single chamber porous silicon formation system. The formation system consists of a container 306 filled with a chemical mixture 307 of HF and ethanol, a platinum electrode 308 connecting to a negative electricity 310, a conductive sucking disc 309 connecting to a positive electricity 311, a tube 312 connecting to a vacuum system 313. The conductive sucking disc 309 comprises of platinum, nickel, graphite or the like. The silicon plate 301 with the porous silicon layer 314 is attached onto the lower surface of the disc 309 by a differential pressure between the vacuum system 313 and atmosphere pressure. Since the low resistance layer 304 is kept in tough contact with the disc 309 the positive electricity can be applied to the silicon plate 301. Anodic dissolution of silicon is used to form the porous silicon layer 314. The porosity of the porous silicon layer 314 is controlled by choosing the proper values of the formation parameters such as current density and HF concentration in the solution. The porous silicon layer 314 has a porosity ranging from 10 to 30%. It should be noted that the anodic dissolution is self-stopped at the interface between the silicon epitaxial layer 305 and the silicon plate 301 because the silicon plate 301 is not able to anodize due to its lower doped concentration. In a result, the anodic dissolution does not expense the silicon plate 301 during the anodic dissolution and the thickness of the porous silicon layer 314 is the similar to the thickness of the silicon epitaxial layer 305.

FIG. 3C shows a cross-sectional view of a perforated silicon plate assembly at fabrication step 3. At this step, a second silicon epitaxial layer is grown on the surface of the porous silicon layer 314. After loading into the epitaxial furnace the porous silicon layer 314 is initially heated to 1100° C. in a hydrogen environment at atmospheric pressure. Annealing in hydrogen is used to close the surface pores of the porous silicon layer 314. The epitaxial conditions are similar to the epitaxial conditions above described for the first epitaxial growth except the follows. The epitaxy divided into two steps: high doped growth and low doped growth. The resulted epitaxial layer includes a p⁺-layer 315A with a sheet resistance of 50-200 ohm/square and a thickness of 1-2 microns and a p-layer 315B with a resistivity of 0.1-2 ohm-cm and a thickness of 5-20 microns.

Then phosphorous deposition is performed at 850 to 950° C. for 10-30 min with POCl₃ and drive in is performed at 1050° C. in nitrogen for 30 to 1 hour to form a P-N junction including an n⁺-layer 316A with a sheet resistance of 50-100 ohm/square and an n-layer 316B with a junction depth of 0.5 to 3 microns. The metal contact pattern 317 is formed on the surface of the P-N junction by screen-printing using standard aluminum paste and Ag/Al paste. This is followed by baking and co-firing at 750° C. in a furnace.

Next, a transparent plate 318 comprising of glass, plastic or the like is bonded onto the top surface of the P-N junction by applying a transparent adhesive 321. The transparent plate 318 has an antireflective film 319 on the front surface and a metal contact pattern 320 on the back surface. After bonding the metal contact pattern 320 and the metal contact pattern 317 on the surface of the P-N junction are joined together at the edge of the transparent plate 318.

As shown in FIG. 3C, the porous silicon layer 314 is etched away by a diluted alkaline solution 322 comprising of KOH, NaOH, or the like so as to form a gap 324. The alkaline solution 322 reaches the porous silicon layer 314 through the through holes 303A. Since the size of the pores of the porous silicon layer range from 100 to 1000 angstroms the alkaline solution 322 is easy to enter the pores via capillary osmosis. Owing its enormous inner surface, the porous silicon reacts heavily with alkaline agents. To avoid destroying the silicon solar cell by violent reaction, a three-step process is carried out. The first step utilizes very week KOH (0.1%). Then KOH concentration is increased up to 1% and finally 10% for 5 min at room temperature. With these conditions, neither the solar cells and nor the holes matrix is attacked by the KOH solution. Etching starts from the top regions of the through holes 303A so as to form a plurality of small voids. After all the small voids merge together and the alkaline solution flows out from the edge 323 of the silicon plate 301 the transferring of the silicon solar cell onto the transparent plate 318 is finished. Then a metal contact pattern is formed on the back surface of the P-N junction, which is exposed after transferring. The surface of the silicon plate 301 is still shiny and can be reused for epitaxy directly.

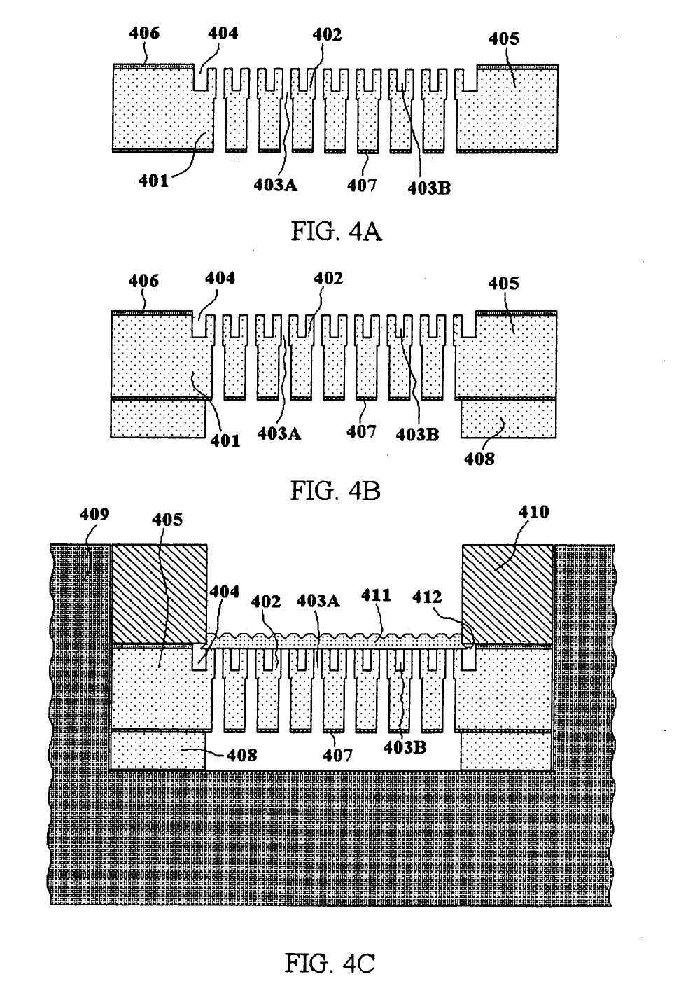

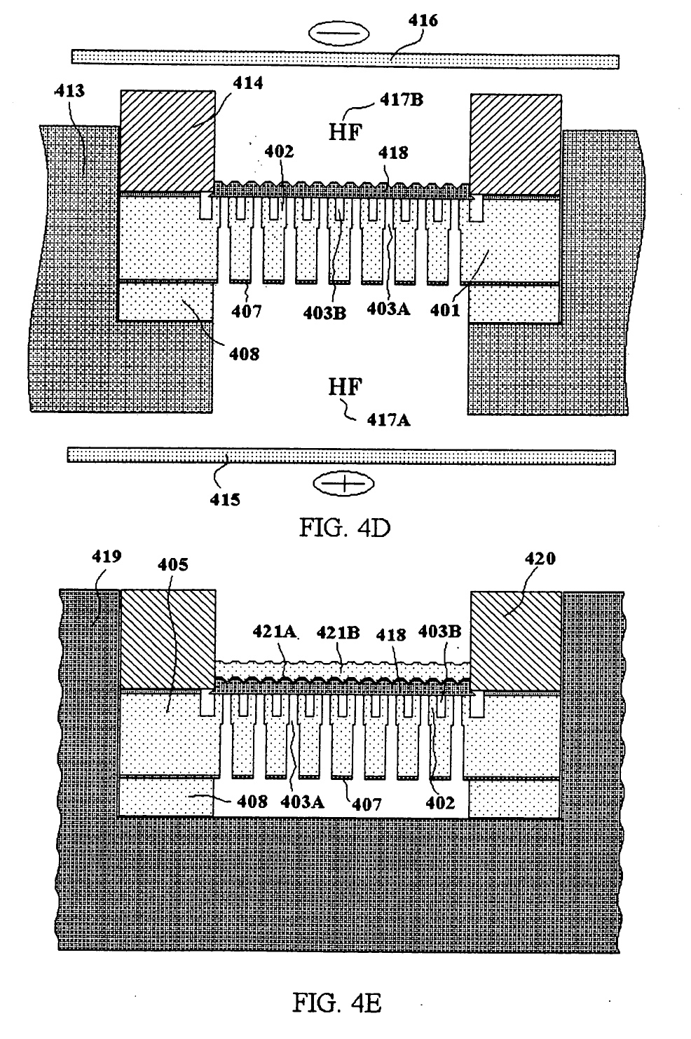

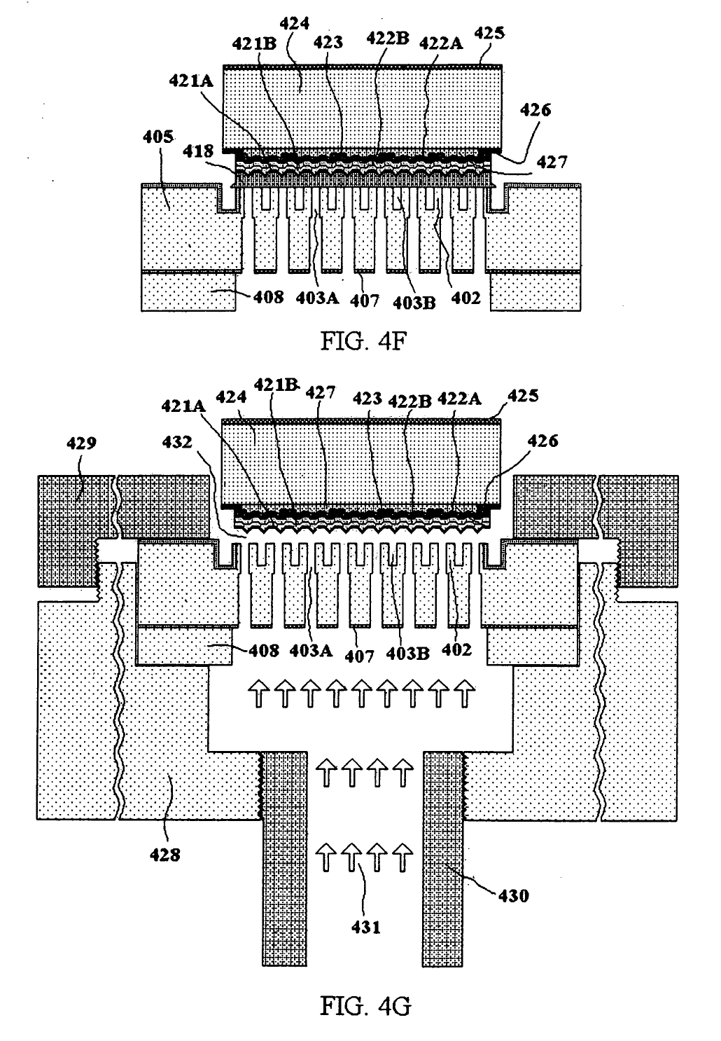

According to the second embodiment of the present invention a method for fabricating a perforated monocrystalline silicon plate assembly for forming and transferring of monocrystalline silicon thin film solar cells is shown as FIG. 4A to FIG. 4G.

FIG. 4A shows a perforated monocrystalline silicon plate assembly for forming and transferring of monocrystalline silicon thin film solar cells at fabrication step 1. At this step, a monocrystalline silicon plate 401 is processed by deep reactive ion etching to form a holes matrix including a plurality of hole inter-spacers 402, a plurality of through holes 403A, a plurality of obstructive holes 403B, which is disposed in the central region of the silicon plate 401, a buffer trench 404 recessed into the silicon plate 401 and surrounding the holes matrix, a principle supporting frame 405 extending from the outer side of the buffer trench 404 to the edge of the silicon plate 40 1. It is also formed a protection film 406 by low pressure chemical vapor deposition, which is disposed on the surface of the principle supporting frame 405 and the inner surface of the buffer trench 404, and an ion conductive electrode 407 by thermal diffusion, which is disposed on the backside of the silicon plate 401.

The silicon plate 401 is p-type doped and has a carrier concentration ranging from 1×10¹⁴ to 8×10¹⁵ cm³. As an alternative, the silicon plate 401 is n-type doped and has a carrier concentration ranging from 1×10¹⁴ to 1×/10¹⁶ cm³. The size of the silicon plate 401 ranges from 3 to 12 inches in length and the thickness ranges from 100 to 1000 microns. The area occupied by the holes matrix from ⅔ to ⅚ of the area of the silicon plate 401. The shape of the matrix is square. The through holes 403A and obstructive holes 403B are distributed in two perpendicular directions (X-Y directions) so that between each two adjacent through holes there are N obstructive holes and the number N ranges from 1 to 100. The hole size of the through holes 3403A and obstructive holes 403B ranges from 2 to 20 microns and the hole pitch ranges from 4 to 40 microns. The depth of the obstructive holes 403B ranges from 10 to 50 microns. The shape of the holes is preferred to be square. As an alternative, the shape of the holes is circular. The through holes 403A comprises a narrow upper portion with a depth ranging from 30 to 100 microns and a wider lower portion with a hole size ranging from 5 to 100 microns. The width and depth of the buffer trench 404 ranges from 10 to 50 microns and from 10 to 50 microns, respectively. The protection film 406 comprises of amorphous silicon carbide with a thickness ranging from 1000 angstroms to 2 microns. As an alternative, the protection film 406 comprises of low stress silicon nitride with a thickness ranging from 1000 angstroms to 2 microns. The ion conductive electrode 407 is doped with a similar conduction type impurity to the silicon plate 401 and has a sheet resistance ranging from 1 to 20 ohm/square.

FIG. 4B shows a perforated silicon plate assembly at fabrication step 2. At this step, the silicon plate 401 is further processed to form an additional silicon frame 408 having a central through window with a size as the same as the size of the holes matrix and a thickness ranging from 100 to 2000 microns. In order to bond the additional frame 408 onto the back surface of the silicon plate 401, two wafers are heated up to moderate temperatures to form an initial prebond. Then two wafers are baked at temperature greater than 900° C. to complete the bond and achieve full strength.

FIG. 4C shows a perforated silicon plate assembly at fabrication step 3. At this step, the silicon plate 401 is placed in the recess of a particular graphite boat 409 for a first silicon epitaxy. A cover 410 shields the protection file region 406 and the buffer trench 404 of the silicon plate 401 for confined epitaxial growth. The cover 410 comprises of monocrystalline silicon, quartz, graphite or the like. The graphite boat 409 is loaded into a quartz chamber for vapor phase deposition. The growth stars from the surface of the hole inter-spacers 402. Later, due to lateral overgrowth the growth goes out of the surface of the hole inter-spacer 402, spreading laterally over the through holes 403A and obstructive holes 403B. As a result, the through holes 403A and obstructive holes 403B are finally seated by the lateral grown portion of an silicon epitaxial layer 411 and the surface of the silicon epitaxial layer 411 is also becomes inverted pyramid surface inherently. The epitaxy utilizes high-temperature chemical vapor deposition, which is well established in industry. SiHCl₃(trichlorosilane) is used as the silicon source gas for film growth at 1100° C. at a rate of 1 microns/min. diborane BH₂ is added for p-type doping. As an alternative, SiH₂Cl₂(dichlorosilane) is used as silicon source gas and diluted from 0.5 to 3% in H₂ as carrier gas. Growth temperature varies between 1050 and 1100° C. According to the dilution rate, silicon growth rate varies from 0.5 to 2 microns/min. Prior to the epitaxy wafer clean is in-situ by hydrogen prebake. The epitaxial layer 411 is managed to have a resistivity ranging from 0.001 to 0.1 ohm-cm and a thickness ranging 2 to 20 microns. It should be noted that the lateral overgrowth also performs at the edge of the hole matrix region. The buffer trench 404 is used to allow the epitaxial bird-month 412 formed by the lateral grown to hang over so as to prevent the cover 410 from sticking to the surface of the silicon plate 401.

FIG. 4D shows a perforated silicon plate assembly at fabrication step 4. At this step, the assembly is placed in the holder 413 of a porous silicon formation system. A cover 414 is used to press the assembly in place and also allow only the surface of the silicon epitaxial layer 411 to be exposed. The porous silicon formation system is divided into two chambers by the holder 413 and filled with a chemical mixture of HF and ethanol. In the lower chamber ion current flows from the positive electrode 414 through HF 417A to the ion conduction electrode 407 and in the upper chamber ion current flows from the surface of the epitaxial layer 411 through HF 417B to the negative electrode 415. Anodic dissolution of silicon is used to form porous silicon. The porosity of the porous silicon is controlled by choosing the proper values of the formation parameters such as current density and HF concentration in the solution. The resulted porous silicon layer 418 with a porosity ranging from 10 to 30 is required. The surface of the porous silicon layer 418 becomes an inverted pyramid surface inherently.

It should be noted that the porous silicon layer 418 is selectively formed within the epitaxial layer 411 and the silicon plate 401 is not able to convert into porous silicon due to its lower doped concentration. Therefore, the thickness of the porous silicon layer 418 is similar to the thickness of the silicon epitaxial layer 411.

FIG. 4E shows a perforated silicon plate assembly at fabrication step 5. At this step, the assembly with the porous silicon layer 418 on the surface of the silicon plate 401 is placed in a graphite boat 419 with a cover 420 for confining the eptaxial growth within the surface of the porous silicon 418. The assembly is loaded into a chemical vapor deposition furnace to start a second epitaxial growth. The porous silicon layer 418 is initially heated to 1100° C. in a hydrogen environment at atmospheric pressure. Annealing in hydrogen is used to close the surface pores of the porous silicon layer 418. The epitaxial conditions are the same as the epitaxial conditions above described for the first epitaxial growth except the follows. The resulted silicon epitaxial layer includes a p⁺-layer 421A with a sheet resistance of 50-200 ohm/square and a thickness of 1-2 microns and a p-layer 421B with a resistivity of 0.1 to 2 ohm-cm and a thickness of 5-20 microns.

FIG. 4F shows a perforated silicon plate assembly at fabrication step 6. At this step, phosphorous deposition is performed at 850 to 950° C. for 10-30 min with POCl₃. Drive in is performed at 1050° C. in nitrogen for 30 to 1 hour to form a P-N junction including an n⁺-layer 422A with a sheet resistance of 50-100 ohm/square and an n-layer 422B with a junction depth of 0.5 to 3 microns. The metal contact pattern 423 is formed on the surface of the P-N junction. This is followed by baking and co-firing at 750° C. in a furnace. Then a transparent plate 424 is bonded on the top surface of the metal contact pattern 423 by applying a transparent adhesive 217. The transparent plate 424 comprises of glass, plastic or the like and has been processed to have an anti-reflection 425 film on the front surface, a metal contact pattern 426 on the back surface.

FIG. 4G shows a perforated silicon plate assembly at fabrication step 7. At this step, the assembly with the monocrystalline silicon thin film solar cell is placed in a transferring system, which consists of a housing 428, a cover 429, a tube 430, and a diluted alkaline solution 431 comprising of KOH, NaOH or the like. The housing 428 supports the silicon frame 408 and the cover 429 presses the silicon plate 401 in place. The tube 430 is used to expose the backside of the holes matrix to the diluted alkaline solution 431 so as to allow the alkaline solution to reach the porous silicon layer 418 via the through holes 403A. After etching the porous silicon layer 418 to form a gap 432 the silicon solar cell is separated from the silicon plate 401 and transferred onto the transparent plate 424. Finally a metal contact pattern is formed on the back surface of the P-N junction, which is exposed after transferring. The surface of the silicon plate 401 is still shiny and can be reused for epitaxy directly.

The above description is illustrative and not restrictive. Many variations of the invention will become apparent to those of skill the art upon review of this disclosure. Merely by way of preferred embodiment, while the invention is illustrated primarily with regard to a perforated monocrystalline silicon plate assembly for forming and transferring of monocrystalline silicon thin film solar cells, the invention is not so limited. The scope of the invention should, therefore, be determined not with reference to the above description, but instead should be determined with reference to the appended claims along with their full scope of equivalents.

What is claimed is:

1. A perforated monocrystalline silicon plate assembly for forming and transferring of monocrystalline silicon thin film solar cells comprising:
a monocrystalline silicon plate;
a hole matrix having a plurality of through holes and obstructive holes, which is disposed over said silicon plate; and
a low resistance layer disposed on the backside of said silicon plate.

2. A perforated monocrystalline silicon plate assembly according to claim 1, where said silicon plate has a size ranging from 1 to 12 inches in length, and a thickness ranging from 100 to 1000 microns.

3. A perforated monocrystalline silicon plate assembly according to claim 1, where said silicon plate is p-type doped and has a carrier concentration ranging from 1×10¹⁴ to 8×10¹⁵ /cm³.

4. A perforated monocrystalline silicon plate assembly according to claim 1, where said silicon plate is n-type doped and has a carrier concentration ranging from 1×10¹⁴ to 1×10¹⁶/cm³.

5. A perforated monocrystalline silicon plate assembly according to claim 1, where said through holes and obstructive holes are distributed in two perpendicular directions (X-Y directions) so that between each two adjacent through holes there are N obstructive holes and the number N ranges from 1 to 100, the hole size ranges from 2 to 20 microns, the hole pitch ranges from 4 to 40 microns and the depth of the obstructive holes ranges from 10 to 50 microns.

6. A perforated monocrystalline silicon plate assembly according to claim 5, where said through holes comprises a narrow upper portion with a depth ranging from 30 to 100 microns and a wider lower portion with a hole size ranging from 5 to 100 microns.

7. A perforated monocrystalline silicon plate assembly according to claim 1, where said low resistance layer is doped with a similar conduction type impurity to said silicon plate and has a sheet resistance ranging from 1 to 20 ohm/square.

8. A perforated monocrystalline silicon plate assembly according to claim 1 further comprising a monocrystalline silicon thin film solar cell consisting of a porous silicon layer with an inverted pyramid surface, which is disposed on the surface of said hole matrix, a silicon P-N junction including a p⁺-layer, a p-layer, an n⁺-layer and an n-layer, which has an inverted pyramid surface and is disposed on the surface of said porous silicon layer, a metal contact pattern disposed on the surface of said P-N junction, and a transparent plate comprising of glass or plastics and having an antireflective film on the front surface and a metal contact pattern on the back surface, which is bonded onto the top surface of said metal contact pattern of said P-N junction by applying a transparent adhesive layer there between.

9. A perforated monocrystalline silicon plate assembly according to claim 1 further comprising a transferring means, which allows a diluted alkaline solution comprising of KOH, NaOH or the like to reach said porous silicon layer via said through holes and etching said porous silicon layer.

10. A perforated monocrystalline silicon plate assembly for forming and transferring of monocrystalline silicon thin film solar cells comprising:
a monocrystalline silicon plate,
a hole matrix disposed in the central region of said silicon plate and having a plurality of through holes and obstructive holes,
a buffer trench recessed into said silicon plate and surrounding said hole matrix,
a principal silicon frame disposed outside said buffer trench and supporting said holes matrix,
a protection film disposed on the surface of said silicon frame and the inner surface of said trench, and
an ion conductive electrode disposed on the backside of said silicon plate.

11. A perforated monocrystalline silicon plate assembly according to claim 10, where said silicon plate has a size ranging from 1 to 12 inches in length and a thickness ranging from 100 to 1000 microns.

12. A perforated monocrystalline silicon plate assembly according to claim 10, where said silicon plate is p-type doped and has a carrier concentration ranging from 1×10¹⁴ to 8×10¹⁵ /cm³.

13. A perforated silicon plate assembly according to claim 10, where said silicon plate is n-type doped and has a carrier concentration ranging from 1×10¹⁴ to 1×10¹⁶/cm³.

14. A perforated monocrystalline silicon plate assembly according to claim 10, where said hole matrix has a matrix size ranging from ⅔ to ⅚ of said silicon plate size, said through holes and obstructive holes are distributed in two perpendicular directions (X-Y directions) so that between each two adjacent through holes there are N obstructive holes and the number N ranges from 1 to 100, the hole size ranges from 2 to 20 microns, the hole pitch ranges from 4 to 40 microns, the depth of the obstructive holes ranges from 10 to 50 microns.

15. A perforated monocrystalline silicon plate assembly according to claim 14, where said through holes comprises a narrow upper portion with a depth ranging from 30 to 100 microns and a wider lower portion with a hole size ranging from 5 to 100 microns.

16. A perforated monocrystalline silicon plate assembly according to claim 10, where said buffer trench has a width ranging from 10 to 50 microns and a depth ranging from 10 to 50 microns.

17. A perforated monocrystalline silicon plate assembly according to claim 10, where said protection film comprises of amorphous silicon carbide or low stress silicon nitride and has a thickness ranging from 1000 angstroms to 2 microns.

18. A perforated monocrystalline silicon plate assembly according to claim 10, where said ion conductive electrode is a diffusion layer formed on the backside of said silicon plate, which is doped with a similar conduction type impurity to said silicon plate and has a sheet resistance ranging from 1 to 20 ohm/square.

19. A perforated monocrystalline silicon plate assembly according to claim 10 further comprising an additional silicon frame bonded on the back surface of said principle silicon frame, which has a thickness ranging from 400 to 2000 microns and a central through window with a size as the same as the size of said hole matrix.

20. A perforated monocrystalline silicon plate assembly according to claim 10 further comprising a monocrystalline silicon thin film solar cell consisting of a porous silicon layer with an inverted pyramid surface, which is disposed on the surface of said hole matrix, a silicon P-N junction including a p⁺-layer, a p-layer, an n⁺-layer and an n-layer, which is disposed on the surface of said porous silicon layer, a metal contact pattern disposed on the surface of said P-N junction, and a transparent plate comprising of glass or plastic and having an antireflective film on the front surface and a metal contact pattern on the back surface, which is bonded onto the top surface of said metal contact pattern of said P-N junction by applying a transparent adhesive layer there between.

21. A perforated monocrystalline silicon plate assembly according to claim 10 further comprising a transferring system, which consists of a housing for holding said silicon plate, a cover with an outer ring for pressing said silicon plate in place and a central window for revealing said solar cell, and a tube allowing a diluted alkaline solution comprising of KOH, NaOH or the like to reach said porous silicon layer via said through holes and etching said porous silicon layer.

22. A method for making a perforated silicon plate assembly for forming and transferring of monocrystalline silicon thin film solar cells, comprising steps:
(a) providing a monocrystalline silicon plate having a size ranging from 1 to 12 inches in length, a thickness ranging from 100 to 10000 microns,
(b) perforating said silicon plate by deep reactive ion etching so that a hole matrix with a plurality of through holes and obstructive holes is formed, the through holes and obstructive holes are distributed in two perpendicular directions (X-Y directions) so that between each two adjacent through holes there are N obstructive holes and the number N ranges from 1 to 100, the hole size ranges from 2 to 20 microns, the hole pitch ranges from 4 to 40 microns, the depth of the obstructive holes ranges from 10 to 50 microns, the through holes comprises a narrow upper portion with a depth ranging from 30 to 100 microns and a wider lower portion with a hole size ranging from 5 to 100 microns.
(c) performing thermal diffusion using a doping impurity with a conduction type being similar to the doping impurity of said silicon plate, so as to form a low resistance layer disposed on the backside of said silicon plate and having a sheet resistance ranging from 1 to 20 ohm/square.

23. The method of claim 22, where said silicon plate is p-type doped and has a carrier concentration ranging from 1×10¹⁴ to 8×10¹⁵/cm³.

24. The method of claim 22, where said silicon plate is n-type doped and has a carrier concentration ranging from 1×10¹⁴ to 1×1016/cm3.

25. The method of claim 22, further comprising the following steps:
(d) growing a first p-type epitaxial monocrystalline silicon layer with an inverted pyramid surface on the surface of said hole matrix by vapor phase epitaxy so as to have a resistivity ranging from 0.001 to 0.1 ohm-com and a thickness ranging 2 to 20 microns,
(e) selectively converting said silicon epitaxial layer into a monocrystalline porous silicon layer with an inverted pyramid surface by anodization in HF solution,
(f) growing a second p-type silicon epitaxial layer with an inverted pyramid surface, which includes a p⁺-layer and a p-layer on the surface of said porous silicon layer by vapor phase epitaxy so that the p⁺-layer has a sheet resistance ranging from 50 to 200 ohm/square, the p-layer has a resistivity ranging from 0.1 to 2 ohm-com and a thickness ranging 2 to 20 microns,
(g) performing thermal diffusion to form a silicon P-N junction including a n⁺-layer and a n-layer in said second silicon epitaxial layer so that the n⁺-layer has a sheet resistance ranging from 50 to 200 ohm/square and the n-layer has a junction depth ranging 0.5 to 3 microns,
(h) forming a metal contact pattern on the surface of said P-N junction,
(i) bonding a transparent plate comprising of glass or plastic and having an antireflective film on the front surface and a metal contact pattern on the back surface onto the top surface of said metal contact pattern of said P-N junction by applying a transparent adhesive layer,
(j) allowing a diluted alkaline solution comprising of KOH, NaOH or the like to reach said porous silicon layer via said through holes and selectively etch said porous silicon layer so that said silicon thin film solar cell is separated from said silicon plate and transferred onto said transparent plate, and
(k) forming a metal contact pattern on the back surface of said P-N junction, which is exposed after transferring.

26. A method for making a perforated silicon plate assembly for forming and transferring of monocrystalline silicon thin film solar cells, the method comprising:
(a) providing a monocrystalline silicon plate having a size ranging from 1 to 12 inches in length, a thickness ranging from 100 to 10000 microns,
(b) perforating said silicon plate by deep reactive ion etching so that a hole matrix with a plurality of through holes and obstructive holes is formed, the through holes and obstructive holes are distributed in two perpendicular directions (X-Y directions) so that between each two adjacent through holes there are N obstructive holes and the number N ranges from 1 to 100, the hole size ranges from 2 to 20 microns, the hole pitch ranges from 4 to 40 microns, the depth of the obstructive holes ranges from 10 to 50 microns, the through holes comprises a narrow upper portion with a depth ranging from 30 to 100 microns and a wider lower portion with a hole size ranging from 5 to 100 microns.
(c) forming a buffer trench by deep reactive ion etching of said silicon plate, which surrounds said hole matrix and has a width ranging from 10 to 50 microns and a depth ranging from 10 to 50 microns,
(d) depositing a protection film on the surface of a principle silicon frame, which expends from the outer side of said buffer trench to the edge of said silicon plate, comprises of amorphous silicon carbide or low stress silicon nitride and has a thickness ranging from 1000 angstroms to 2 microns, and
(e) performing thermal diffusion to form an ion conductive electrode layer on the backside of said silicon plate using a similar conduction type doping impurity to the doping impurity of said silicon, which has a sheet resistance ranging from 1 to 20 ohm/square and a junction depth ranging from 2000 angstroms to 2 microns.

27. The method of claim 26, where said silicon plate is p-type doped and has a carrier concentration ranging from 1×10¹⁴ cm³ to 8×10¹⁵ /cm³.

28. The method of claim 26, where said silicon plate is n-type doped and has a carrier concentration ranging from 1×10¹⁴ to 1×10¹⁶/cm³.

29. The method of claim 26, further comprising the following steps:
(f) growing a first p-type epitaxial monocrystalline silicon layer with an inverted pyramid surface on the surface of said hole matrix by vapor phase epitaxy so as to have a resistivity ranging from 0.001 to 0.1 ohm-com and a thickness ranging 2 to 20 microns,
(g) selectively converting said p-type silicon epitaxial layer into a porous silicon layer with an inverted pyramid surface by anodization in HF solution,
(h) growing a second p-type silicon epitaxial layer with an inverted pyramid surface, which includes a p⁺-layer and a p-layer on the surface of said porous silicon layer by vapor phase epitaxy, whose p-layer has a resistivity ranging from 1 to 20 ohm-com and a thickness ranging 2 to 20 microns, and whose p⁺-layer has a sheet resistance ranging from 50 to 200 ohm/square,
(i) performing thermal diffusion to form a silicon P-N junction including a n⁺-layer and a n-layer in said silicon epitaxial layer, whose n-layer has a junction depth ranging 0.5 to 3 microns and whose n⁺-layer has a sheet resistance ranging from 50 to 200 ohm/square,
(j) forming a metal contact pattern on the surface of said P-N junction, and
(k) bonding a transparent plate comprising of glass or plastic and having an antireflective film on the front surface and a metal contact pattern on the back surface onto the top surface of said metal contact of said P-N junction by applying a transparent adhesive layer.

30. The method of claim 26, further comprising the following steps:
(l) preparing a transferring system consisting of a housing for holding said silicon plate, a cover with an edge region for pressing said silicon plate in place and a central window for revealing said monocrystalline silicon thin film solar cell, a diluted alkaline solution, and a tube filled with said diluted alkaline solution,
(m) placing said perforated silicon plate assembly with said silicon thin film solar cell into said transferring system,
(n) allowing said diluted alkaline solution comprising of KOH, NaOH or the like to reach said porous silicon layer via said through holes and selectively etch said porous silicon layer so that said silicon solar cell is separated from said silicon plate and transferred onto said transparent plate, and
(o) forming a metal contact pattern on the back surface of the said P-N junction, which is exposed after transferring.
